(19) United States
(12) Patent Application Publication
(10) Pub. No.: US 2025/0105840 A1
(43) Pub. Date: Mar. 27, 2025

(54) GATE DRIVER CIRCUIT, MOTOR DRIVE DEVICE USING SAME, AND ELECTRONIC DEVICE

(71) Applicant: ROHM CO., LTD., Kyoto (JP)

(72) Inventor: Hisashi SUGIE, Kyoto (JP)

(21) Appl. No.: 18/888,642

(22) Filed: Sep. 18, 2024

(30) Foreign Application Priority Data
Sep. 22, 2023 (JP) 2023-159106

(51) Int. Cl. H03K 17/687; H02P 27/00

(52) U.S. Cl. CPC H03K 17/6871; H02P 27/00; H03K 2217/0063; H03K 2217/0072

(57) ABSTRACT

A gate driver circuit for driving an N-type power transistor that constitutes a switching circuit, includes: a high-level line on which a voltage higher than a source of the power transistor is generated; a turn-on transistor configured to source a current to a gate of the power transistor; a turn-off transistor configured to sink a current from the gate of the power transistor; and a control circuit, wherein the turn-on transistor includes a plurality of transistors connected between the gate of the power transistor and the high-level line, and wherein the control circuit controls on/off states of the plurality of transistors so that when turning the power transistor on, the turn-on transistor has a first drive capability in a first period, a second drive capability lower than the first drive capability in a second period, and a third drive capability higher than the second drive capability in a third period.

### CROSS-REFERENCE TO RELATED APPLICATION

This application is based upon and claims the benefit of priority from Japanese Patent Application No. 2023-159106, filed on Sep. 22, 2023, the entire contents of which are incorporated herein by reference.

### TECHNICAL FIELD

The present disclosure relates to a gate driver circuit.

### BACKGROUND

A half-bridge circuit, an H-bridge circuit, and a three-phase bridge circuit (hereinafter collectively referred to as bridge circuits) using power transistors are widely used in a motor driver circuit, a DC/DC converter, a power conversion device, and the like.

FIG. 1 is a circuit diagram of a bridge circuit 10. The bridge circuit 10 includes an upper arm 12 and a lower arm 14 that are connected in series between a power supply terminal and a ground terminal. The upper arm 12 includes a high-side transistor MH and a flywheel diode Di that are connected in parallel. The lower arm 14 includes a low-side transistor ML and a flywheel diode Di that are connected in parallel. An inductor (coil) L1, which serves as a load, is connected to an output terminal of the bridge circuit 10.

The bridge circuit 10 can take the following states: a state 1 in which both the high-side transistor MH and the low-side transistor ML are turned off (high impedance state), a state q2 in which the high-side transistor MH is turned on and the low-side transistor ML is turned off (high output state), and a state φ3 in which the high-side transistor MH is turned off and the low-side transistor ML is turned on (low output state). For each of the states φ1 to φ3, there exist a current source state in which a current I_{OUT} is output from the bridge circuit 10 (the current flows to the right-hand side in the figure), and a current sink state in which the bridge circuit 10 absorbs the current I_{OUT} (the current flows to the left-hand side in the figure).

### BRIEF DESCRIPTION OF DRAWINGS

The accompanying drawings, which are incorporated in and constitute a part of the specification, illustrate embodiments of the present disclosure.

FIG. 1 is a circuit diagram of a bridge circuit.

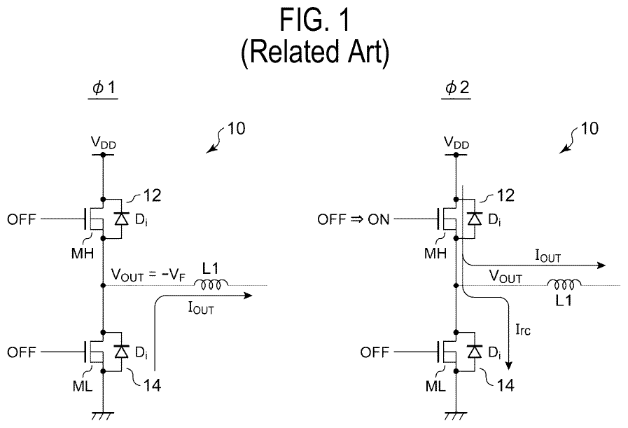

FIG. 2 is a circuit diagram of a switching circuit according to an embodiment.

FIG. 3 is a circuit diagram of a gate driver circuit according to an embodiment.

FIG. 4 is an operational waveform diagram of the gate driver circuit shown in FIG. 3.

FIG. 5 is a circuit diagram of a drive circuit including the gate driver circuit.

FIG. 6 is a circuit diagram of a turn-on circuit according to modification 1.

FIG. 7 is a circuit diagram of a turn-on circuit according to modification 2.

FIG. 8 is a waveform diagram showing an operation (simulation results) of the turn-on circuit shown in FIG. 7.

FIG. 9 is a circuit diagram of the drive circuit.

FIG. 10 is a circuit diagram of a motor drive device including the switching circuit according to the embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Overview of Embodiments

An overview of some exemplary embodiments of the present disclosure will be described. This overview is intended to provide a simplified explanation of some concepts of one or more embodiments for the purpose of providing a basic understanding of the embodiments as a prelude to the detailed description that follows, and is not intended to limit the scope of the invention or disclosure. For the sake of convenience, the term “one embodiment” may be used to refer to one embodiment (example or modification) or multiple embodiments (examples or modifications) disclosed in this specification.

This overview is not an exhaustive overview of all conceivable embodiments, and is not intended to identify key elements of all embodiments or to delineate the scope of some or all aspects. Its sole purpose is to present some concepts of one or more embodiments in a simplified form as a prelude to the more detailed description which is presented later.

A gate driver circuit according to one embodiment drives an N-type power transistor constituting a switching circuit. The gate driver circuit includes a high-level line on which a voltage higher than a source of the power transistor is generated, a turn-on transistor configured to source a current to a gate of the power transistor, a turn-off transistor configured to sink a current from the gate of the power transistor, and a control circuit for controlling the turn-on transistor and the turn-off transistor. The turn-on transistor includes a plurality of transistors connected between the gate of the power transistor and the high-level line. The control circuit controls on/off states of the plurality of transistors so that when turning the power transistor on, the turn-on transistor has a first capability in a first period, a second capability lower than the first capability in a second period, and a third capability higher than the second capability in a third period.

The current drive capability of the turn-on transistor (also simply referred to as drive capability or capability) is a sum of the drive capabilities of transistors in an on state among the plurality of transistors, and the drive capability of each transistor is defined by W/L (gate width/gate length). In the first to third periods, the current flowing through the turn-on transistor is defined by the drive capability of the turn-on transistor.

According to the above configuration, a drive current having a first current amount is supplied to the gate of the power transistor during the first period until the power transistor is turned on, thereby increasing a gate voltage. Then, after the power transistor is turned on, during the second period during which a reverse recovery current may flow through the flywheel diode of the opposite arm, the drive current supplied to the gate of the power transistor is reduced to slowly turn on the power transistor while keeping an on-resistance of the power transistor large. This makes it possible to suppress a through-current and ringing caused by the reverse recovery current of the flywheel diode of the opposite arm. Subsequently, during the third period during which the reverse recovery current is less likely to flow, the amount of current supplied to the gate is increased more than that during the second period, thereby shortening a turn-on time of the power transistor and reducing power consumption. Further, during both the first and second periods, a first current mirror circuit operates and an amount of input current of the first current mirror circuit is switched, so that the current supplied to the gate is changed slowly when switching to the second period. This makes it possible to further reduce the power consumption.

In one embodiment, the third capability may be higher than the first capability. That is, the current supplied to the gate of the power transistor in the third period may be higher than the current supplied to the gate of the power transistor in the first and second periods. After influence of the reverse recovery characteristic of the flywheel diode of the opposite arm becomes small, the amount of current supplied to the gate of the power transistor is increased, whereby the on-resistance of the power transistor can be reduced in a short time and efficiency of the bridge circuit can be improved.

In one embodiment, the plurality of transistors may include at least one transistor assigned to a first transistor group and at least one transistor assigned to a second transistor group. The control circuit may fix the at least one transistor assigned to the second transistor group to an off state in the second period, without changing the on/off state of the at least one transistor assigned to the first transistor group over the first period to the third period. In the second period, only the transistors included in the first transistor group may be turned on. As a result, when transitioning from the first period to the second period and when transitioning from the second period to the third period, only one of turning-on and turning-off of the transistors occurs. This makes it possible to suppress discontinuity of a current.

In one embodiment, the control circuit may control the on/off states of the plurality of transistors so that the turn-on transistor has a fourth capability higher than the third capability in a fourth period. This makes it possible to fix the power transistor to an on state.

In one embodiment, the plurality of transistors may have a same size.

In one embodiment, the plurality of transistors may have binary weighted sizes.

In one embodiment, the gate driver circuit may further include a first sensor that compares a gate-source voltage of the power transistor with a first threshold voltage. The control circuit may perform a transition to the second period in response to a change in an output of the first sensor in the first period. By monitoring the gate-source voltage of the power transistor, a magnitude of a drive current can be changed in conjunction with transition of the power transistor from an off state to an on state. The first threshold voltage may be equal to, higher than, or lower than a gate threshold value of a MOSFET.

In one embodiment, the first sensor may be shared with a high-side off sensor that detects turning-off of the high-side transistor. This makes it possible to reduce the drive current before the high-side transistor is turned on. In addition, it is possible to suppress an increase in circuit area.

In one embodiment, the gate driver circuit may further include a second sensor that compares an output voltage of the switching circuit with a second threshold voltage. The control circuit may perform a transition to the third period in response to a change in an output of the second sensor in the second period. By monitoring the output voltage, it is possible to detect that the influence of the reverse recovery characteristic of the flywheel diode of the opposite arm has become smaller.

In one embodiment, the gate driver circuit may further include a third sensor that compares the output voltage of the switching circuit with a third threshold voltage. The control circuit may perform a transition to the fourth period in response to a change in an output of the third sensor during the third period.

In one embodiment, the gate driver circuit may be integrated on a single semiconductor substrate. The term “integrated” includes a case where all components of a circuit are formed on a semiconductor substrate, and a case where main components of a circuit are integrated while some resistors, capacitors, and the like for adjusting a circuit constant may be provided outside the semiconductor substrate. By integrating a circuit on a single chip, the circuit area can be reduced and characteristics of circuit elements can be kept uniform.

A motor drive circuit according to one embodiment includes a bridge circuit including a high-side transistor and a low-side transistor, a high-side driver which is any one of the above-described gate driver circuits that drives the high-side transistor as a power transistor, and a low-side driver which is any one of the above-described gate driver circuits that drives the low-side transistor as a power transistor.

An electronic device according to one embodiment includes a motor and the above-described motor drive device configured to drive the motor.

### Embodiment

A preferred embodiment will be described below with reference to the drawings. The same or equivalent components, parts, and processes shown in each drawing are designated by like reference numerals, and duplicate descriptions are omitted as appropriate. Furthermore, the embodiment is exemplary rather than limitative. All of the features and combinations thereof described in the embodiment are not necessarily essential to the present disclosure.

In the present disclosure, the expression “a state where a member A is connected to a member B” includes a case where the member A and the member B are physically directly connected or even a case where the member A and the member B are indirectly connected via any other member that does not affect an electrical connection state between the members A and B or does not impair functions and effects achieved by combinations of the members A and B. Similarly, the expression “a state where a member C is installed between a member A and a member B” includes a case where the member A and the member C or the member B and the member C are indirectly connected via any other member that does not affect an electrical connection state between the members A and C or the members B and C or does not impair functions and effects achieved by combinations of the members A and C or the members B and C, in addition to a case where the member A and the member C or the member B and the member C are directly connected.

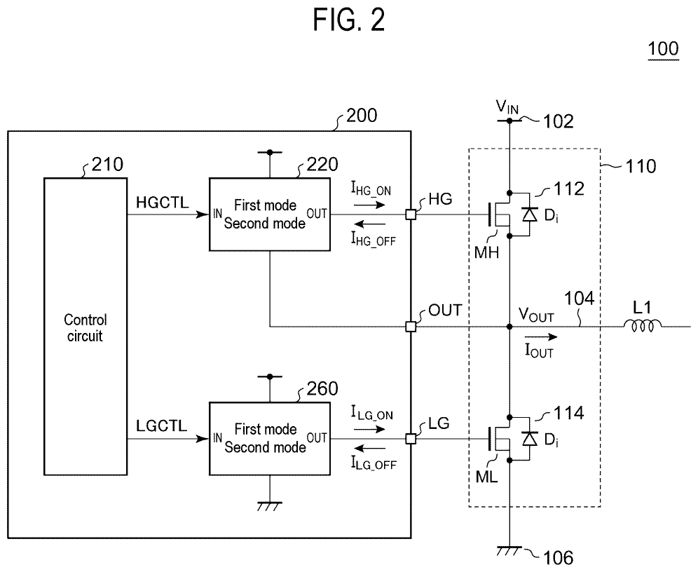

FIG. 2 is a circuit diagram of a switching circuit 100 according to an embodiment. The switching circuit 100 includes a bridge circuit 110 and a drive circuit 200. Although only a configuration of one phase of the switching circuit 100 is shown here, the switching circuit 100 may be a three-phase circuit or an H-bridge circuit.

The bridge circuit 110 includes an upper arm 112 provided between a power supply line (input line) 102 and an output terminal (output line) 104, and a lower arm 114 provided between the output line 104 and a ground line 106. The upper arm 112 includes a high-side transistor MH and a flywheel diode (freewheel diode) Di connected in parallel. The lower arm 114 includes a low-side transistor ML and a flywheel diode Di connected in parallel. In the present embodiment, the high-side transistor MH and the low-side transistor ML are N-channel MOSFETs, and a body diode of each of them also functions as the flywheel diode Di.

The drive circuit 200 controls the upper arm 112 and the lower arm 114 of the bridge circuit 110. The drive circuit 200 is switched among three states: a high impedance state φ1 in which both the upper arm 112 and the lower arm 114 are turned off, a high output state φ2 in which the upper arm 112 is turned on and the lower arm 114 is turned off, and a low output state φ3 in which the upper arm 112 is turned off and the lower arm 114 is turned on. A direction of an output current I_{OUT} flowing from the output line 104 of the bridge circuit 110 toward an inductor L1, which is a load, is taken as positive, and an opposite direction is taken as negative. For each of the three states φ1 to φ3, there are states φ1A to φ3A in which the output current I_{OUT} is positive (current source) and states φ1B to φ3B in which the output current I_{OUT} is negative (current sink).

The drive circuit 200 is a functional IC that includes a control circuit 210, a high-side driver circuit 220, and a low-side driver circuit 260, and is integrated on a single semiconductor substrate. The control circuit 210 selects one of the states φ1 to φ3 according to a load state of the bridge circuit 110, and generates control signals HGCTL and LGCTL corresponding to each of the states φ1 to φ3. In the state φ1, the high-side control signal HGCTL and the low-side control signal LGCTL are both at an off level (e.g., low level). In the state φ2, the high-side control signal HGCTL is at an on level (e.g., high level), and the low-side control signal LGCTL is at an off level. In state φ3, the high-side control signal HGCTL is at an off level, and the low-side control signal LGCTL is at an on level.

The high-side driver circuit 220 receives the high-side control signal HGCTL at an input node IN. An output node OUT is connected to a gate of the high-side transistor MH via a high-side gate pin HG. When the high-side control signal HGCTL transitions from an off level to an on level, the high-side driver circuit 220 supplies a drive current I_{HG_ON} to the gate of the high-side transistor MH, thereby raising a gate-source voltage V_{GS} of the high-side transistor MH and turning the high-side transistor MH on. When the high-side control signal HGCTL transitions from an on level to an off level, the high-side driver circuit 220 draws out a drive current I_{HG_OFF} from the gate of the high-side transistor MH, thereby lowering the gate-source voltage V_{GS} and turning the high-side transistor MH off.

When the high-side transistor MH is turned on, the high-side driver circuit 220 can select a plurality of operation modes, one of which is called a first mode. In the first mode, the high-side driver circuit 220 changes the drive current I_{HG_ON} supplied to the gate of the high-side transistor MH in multiple stages according to a state of the bridge circuit 110.

In the first mode, the high-side driver circuit 220 outputs the drive current I_{HG_ON} having a first current amount I₁ during a first period T1 after the high-side control signal HGCTL transitions from an off level to an on level, outputs the drive current I_{HG_ON} having a second current amount I₂ less than the first current amount I₁ during a second period T2 following the first period T1, and outputs the drive current I_{HG_ON} having a third current amount I₃ greater than the first current amount I₁ and the second current amount I₂ during a third period T3 following the second period T2.

The high-side driver circuit 220 is configured to be operable in a second mode in addition to the first mode. In the second mode, a waveform of the drive current I_{HG_ON} generated by the high-side driver circuit 220 is different from that in the first mode. Specifically, in the second mode, the drive current I_{HG_ON} has a constant amount Ic greater than the second current amount I₂ from a time when the high-side control signal HGCTL transitions from the off level to the on level to a time when state transition of the bridge circuit 110 is completed. The constant amount Ic may be greater than any of the first current amount I₁ to the third current amount I₃.

The low-side driver circuit 260 receives the low-side control signal LGCTL at an input node IN. An output node OUT is connected to a gate of the low-side transistor ML via a low-side gate pin LG. When the low-side control signal LGCTL transitions from an off level (e.g., low level) to an on level (high level), the low-side driver circuit 260 supplies a drive current I_{LG_ON} to the gate of the low-side transistor ML, raises a gate-source voltage Vos of the low-side transistor ML, and turns the low-side transistor ML on. When the low-side control signal LGCTL transitions from an on level to an off level, the low-side driver circuit 260 draws out a drive current I_{LG_OFF} from the gate of the low-side transistor ML, lowers the gate-source voltage V_{GS}, and turns the low-side transistor ML off.

Like the high-side driver circuit 220, the low-side driver circuit 260 is configured to be switchable between a first mode and a second mode.

In the first mode, the low-side driver circuit 260 changes the drive current I_{LG_ON} supplied to the gate of the low-side transistor ML in multiple stages according to a state of the bridge circuit 110.

In the first mode, the low-side driver circuit 260 outputs the drive current I_{LG_ON} having a fourth current amount I₄ during a fourth period T4 after the low-side control signal LGCTL transitions from an off level to an on level, outputs the drive current I_{LG_ON} having a fifth current amount I₅ less than the fourth current amount I₄ during a fifth period T5 following the fourth period T4, and outputs the drive current I_{LG_ON} having a sixth current amount I₆ greater than the fourth current amount I₄ and the fifth current amount I₅ during a sixth period T6 following the fifth period T5.

In the second mode, a waveform of the drive current I_{LG_ON} generated by the low-side driver circuit 260 is different from that in the first mode. Specifically, in the second mode, the drive current I_{LG_ON} has a constant amount Id greater than the fifth current amount I₅ from a time when the low-side control signal LGCTL transitions from the off level to the on level to a time when the state transition of the bridge circuit 110 is completed. The constant amount Id may be greater than any of the fourth current amount I₄ to the sixth current amount I₆.

The above is the configuration of the switching circuit 100. Next, operations of the switching circuit 100 will be described.

First, operations of the high-side driver circuit 220 will be described. The high-side driver circuit 220 operates in the first mode under a situation where a reverse recovery current of the flywheel diode of the lower arm 114 may be generated, and operates in the second mode under a situation where the reverse recovery current of the flywheel diode of the lower arm 114 is not generated.

Specifically, the high-side driver circuit 220 operates in the first mode under a situation (source rise) where the high-side transistor MH is turned on from the state φ1A in which the high-side transistor MH and the low-side transistor ML are turned off and the current I_{OUT} is being sourced via the flywheel diode Di of the lower arm 114.

In addition, the high-side driver circuit 220 operates in the first mode under a situation (sink rise) where the high-side transistor MH is turned on from the state in which the high-side transistor MH is turned off with the low-side transistor ML turned on and the current I_{OUT} is sinking via the low-side transistor ML.

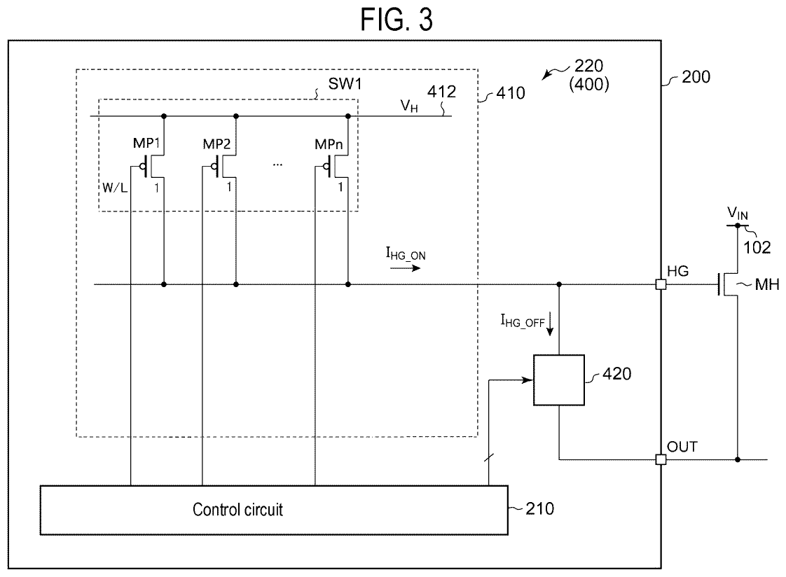

FIG. 3 is a circuit diagram of a gate driver circuit 400 according to an embodiment. Here, the gate driver circuit 400 is the high-side driver circuit 220 shown in FIG. 2, and drives the N-type high-side transistor MH that forms the upper arm.

A turn-on circuit 410 is configured to source the on-current I_{HG_ON} to the gate of the high-side transistor MH, which is an N-type power transistor. A turn-off circuit 420 is configured to sink the current I_{HG_OFF} from the gate of the high-side transistor MH.

The turn-on circuit 410 includes a turn-on transistor SW1. The turn-on transistor SW1 is configured to have a variable drive capability S. Specifically, the turn-on transistor SW1 includes a plurality of transistors MP1 to MPn connected in parallel (between the gate of the high-side transistor MH and a high-level line 412). The transistors MP1 to MPn are configured to be independently switchable between an on state and an off state. The drive capability S of the turn-on transistor SW1 can be adjusted according to the number of transistors that are in an on state among the transistors MP1 to MPn.

A drive capability of the i-th (i=1, 2, . . . , n) transistor MPi is determined by an aspect ratio W/L of a gate width W and a gate length L. Therefore, the drive capability of the turn-on transistor SW1 is a sum of the driving capabilities of transistors that are turned on.

In the present embodiment, it is assumed that the W/Ls, i.e., the driving capabilities, of the plurality of transistors MP1 to MPn are all equal. Therefore, when m out of n transistors (1 ≤m≤n) are turned on, the drive capability of the turn-on transistor SW1 is m times that of one transistor.

The control circuit 210 generates the control signal HGCTL that indicates states of the turn-on transistor SW1 and the turn-off transistor SW2. Specifically, the control circuit 210 is configured to control on/off states of the plurality of transistors MP1 to MPn with respect to the turn-on transistor SW1.

In the first mode, the control circuit 210 operates in the following sequence including a first period T1 to a fourth period T4 in response to an instruction to turn the high-side transistor MH on.

The capability of the turn-on transistor SW1 is set so that the turn-on transistor SW1 operates in a saturation region during the first period T1 to the third period T3. It is considered that during the fourth period T4, the turn-on transistor SW1 operates in a linear region.

### (i) First Period T1

During the first period T1, the capacity of the turn-on transistor SW1 is set to a first capacity S₁. Therefore, a current flowing through the turn-on transistor SW1 does not depend on a drain-source voltage, but is determined by a gate-source voltage and a current capacity. During the first period T1, the current I_{HG_ON} having the first current amount I₁ is supplied to the gate of the high-side transistor MH.

### (ii) Second Period T2

During the second period T2, the capacity of the turn-on transistor SW1 is set to a second capacity S₂ lower than the first capacity S₁. During the second period T2, the current I_{HG_ON} having the second current amount I₂ less than the first current amount I₁ is supplied to the gate of the high-side transistor MH.

### (iii) Third Period T3

During the third period T3, the capacity of the turn-on transistor SW1 is set to a third capacity S₃ higher than the second capacity S₂. The third capacity S₃ may be higher or lower than the first capacity S₁, but is assumed to be higher than the first capacity S₁ herein. During the third period T3, the current I_{HG_ON} having the third current amount I₃, which is greater than the first current amount I₁ and the second current amount I₂, is supplied to the gate of the high-side transistor MH.

### (iv) Fourth Period T4

During the fourth period T4, the capacity of the turn-on transistor SW1 is set to a fourth capacity S₄, which is higher than the first capacity S₁, the second capacity S₂, and the third capacity S₃.

For example, when n=5, control may be executed such that m=2 in the first period T1, m=1 in the second period, m=4 in the third period, and m=5 in the fourth period.

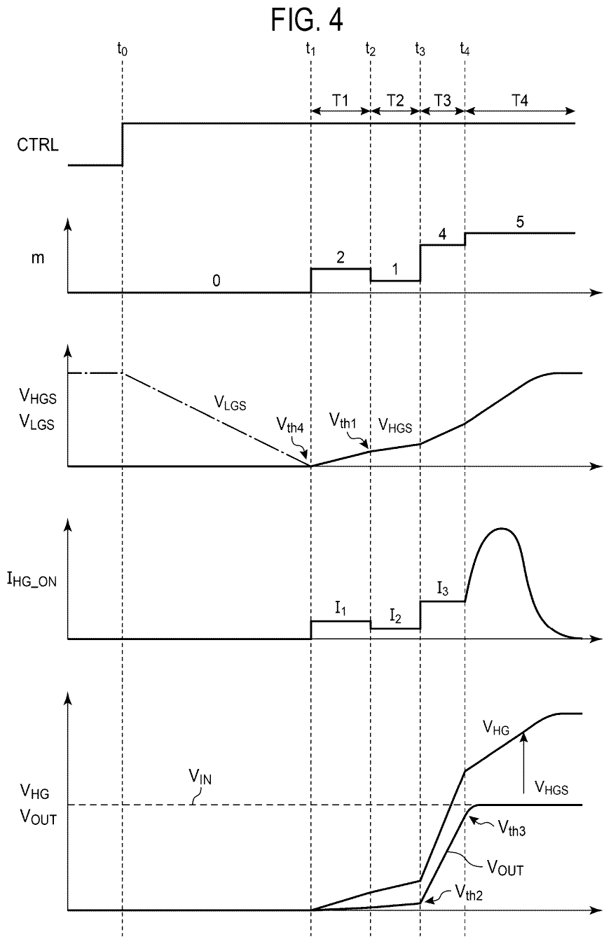

FIG. 4 is an operation waveform diagram of the gate driver circuit 400 shown in FIG. 3. A control signal CTRL is a logic signal that indicates the state of the bridge circuit 110. V_{LGS} is a gate voltage (gate-source voltage) of the low-side transistor ML. V_{HG} is a gate voltage of the high-side transistor MH, and V_{OUT} is a source voltage, i.e., an output voltage of the high-side transistor MH. V_{HGS} is a gate-source voltage of the high-side transistor MH, and is a potential difference between V_{HG} and V_{OUT}.

Before time t₀, the control signal CTRL is at a low level, the high-side transistor MH is turned off, the low-side transistor ML is turned on, and the output voltage V_{OUT} is a low voltage (0 V).

FIG. 4 shows an operation in a current source mode. Before time t₀, a negative current I_{ML} flows through the low-side transistor ML.

At time t₀, the control signal CTRL transitions to a high level. Thus, the low-side driver circuit 260 lowers the gate voltage V_{LG} of the low-side transistor ML and turns the low-side transistor ML off.

At time t₁, when the gate voltage V_{LG} of the low-side transistor ML becomes lower than a fourth threshold voltage Vₜₕ₄, the high-side driver circuit 220 becomes active.

In the first period T1, m=2 transistors are turned on, and the turn-on transistor SW1 has the first capability S₁. At this time, the current I_{HG_ON} having the first current amount I₁ is supplied to the gate of the high-side transistor MH.

Then, when the gate-source voltage V_{HGS} of the high-side transistor MH exceeds a first threshold voltage Vₜₕ₁ at time t₂, the period transitions to the second period T2. In the second period T2, m=1 transistor is turned on, and the turn-on transistor SW1 has the second capability S₂. At this time, the current I_{HG_ON} having the second current amount I₂ is supplied to the gate of the high-side transistor MH. Since the second current amount I₂ is smaller than the first current amount I₁, a rising rate of the gate-source voltage V_{HGS} is less than that in the first period T1.

Then, when the output voltage V_{OUT} exceeds a second threshold voltage Vₜₕ₂ at time t₃, the period transitions to the third period T3. In the third period T3, m=4 transistors are turned on, and the turn-on transistor SW1 has the third capability S₃. At this time, the current I_{HG_ON} having the third current amount I₃ is supplied to the gate of the high-side transistor MH. The third current amount I₃ is greater than the first current amount I₁ and the second current amount I₂, and the rising rate of the gate-source voltage V_{HGS} increases.

Then, when the output voltage V_{OUT} exceeds a third threshold voltage Vₜₕ₃, which is defined in a vicinity of an input voltage V_{IN}, at time t₄, the period transitions to the fourth period T4. In the fourth period T4, m=5 transistors are turned on, the turn-on transistor SW1 has the maximum fourth capability S₄, and the turn-on transistor SW1 is in a fully on state. When the turn-on transistor SW1 is in the fully on state, the gate voltage V_{HG} of the high-side transistor MH is fixed to a high-level voltage, and the high-side transistor MH is fixed to a strongly on state.

The operation of the switching circuit 100 has been described above.

According to the switching circuit 100, the drive current I_{HG_ON} having the first current amount I₁ is supplied to the gate of the high-side transistor MH during the first period T1 immediately before the high-side transistor MH is turned on, thereby raising the gate voltage V_{HG}. Then, during the second period T2 after the high-side transistor MH is turned on and during which the reverse recovery current can flow through the flywheel diode of the lower arm, the drive current I_{HG_ON} supplied to the gate of the high-side transistor MH is reduced to the second current amount I₂, so that the high-side transistor MH is turned on gradually while keeping its on-resistance large. This makes it possible to suppress a through-current and ringing caused by the reverse recovery current of the flywheel diode of the arm on the opposite side to the upper arm, which is the driving target of the drive circuit 200, i.e., the lower arm.

Subsequently, in the third period T3 during which the reverse recovery current is less likely to flow, the drive current I_{HG_ON} supplied to the gate of the high-side transistor MH is increased to the third current amount I₃ that is greater than that in the second period T2, thereby shortening the turn-on time of the high-side transistor MH and reducing the power consumption.

Further, the driving current I_{HG_ON} supplied to the gate of the high-side transistor MH in the third period T3 is greater than the first current amount I₁ in the first period T1. Thus, it is possible to reduce the on-resistance of the high-side transistor MH in a short period of time, thereby further improving efficiency of the bridge circuit.

Next, a configuration example of the turn-off circuit 420 will be described.

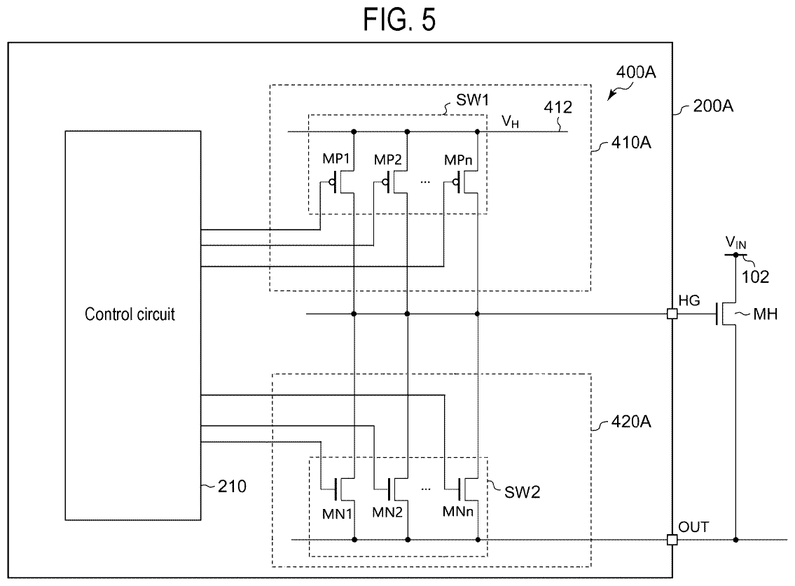

FIG. 5 is a circuit diagram of a drive circuit 200A that includes a gate driver circuit 400A. The gate driver circuit 400A includes a turn-on circuit 410A and a turn-off circuit 420A.

The configuration of the turn-on circuit 410A is similar to that shown in FIG. 3.

The turn-off circuit 420A includes a turn-off transistor SW2. The turn-off transistor SW2 includes a plurality of transistors MN1 to MNn connected in parallel. The number n of transistors MN constituting the turn-off transistor SW2 may be the same as or different from the number n of transistors MP constituting the turn-on transistor SW1.

The transistors MN1 to MNn are configured to be independently switchable between an on state and an off state. A drive capability S of the turn-off transistor SW2 can be adjusted according to the number of transistors that are in an on state among the transistors MN1 to MNn.

According to the turn-off circuit 420A, when turning the high-side transistor MH off, the drive current I_{HG_OFF} generated by the turn-off circuit 420A can be changed in stages, just like the drive current I_{HG_ON} when turning the high-side transistor MH on.

Next, a modification of the turn-on circuit 410 will be described.

### Modification 1

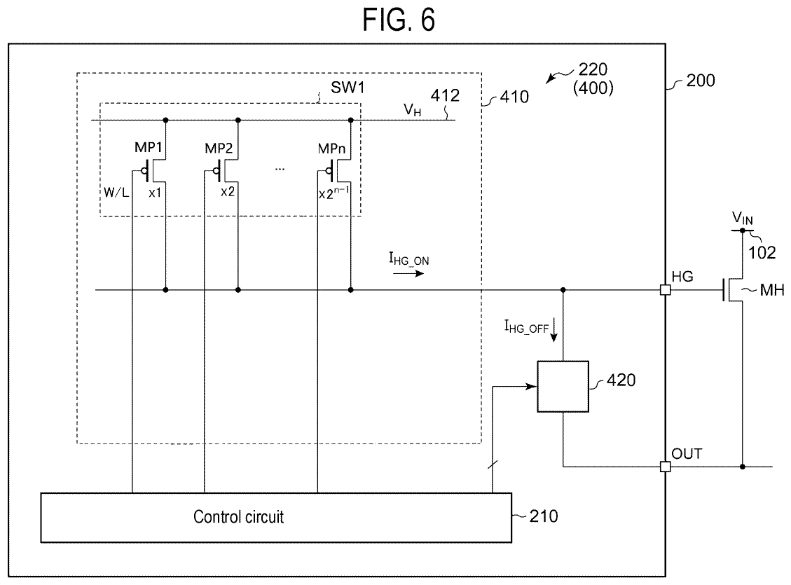

FIG. 6 is a circuit diagram of a turn-on circuit 410 according to modification 1.

The capabilities (sizes) of the plurality of transistors MP1 to MPn constituting the turn-on transistor SW1 may be weighted in binary. Specifically, the W/L ratios of the transistors MP1, MP2, . . . , MPn may satisfy the following relationship: 1:2: . . . : 2ⁿ⁻¹.

When n=5, the W/L ratios of the five transistors MP1 to MP5 are as follows: 1:2:4:8:16.

An example of control in this case is shown below.

(i) First Period T1
MP1 =OFF
MP2 =ON
MP3 =OFF
MP4 =OFF
MP5 =OFF
The capability of the turn-on transistor SW1 during the first period T1 is W/L =2.

(ii) Second Period T2
MP1 =ON
MP2 =OFF
MP3 =OFF
MP4 =OFF
MP5 =OFF
The capability of the turn-on transistor SW1 during the second period T2 is W/L =1.

(iii) Third Period T3
MP1 =OFF
MP2 =OFF
MP3 =OFF
MP4 =OFF
MP5 =ON
The capability of the turn-on transistor SW1 during the third period T3 is W/L =16.

(iv) Fourth Period T4
MP1 =ON
MP2 =ON
MP3 =ON
MP4 =ON
MP5 =ON
The capability of the turn-on transistor SW1 during the fourth period T4 is W/L =31.

### Modification 2

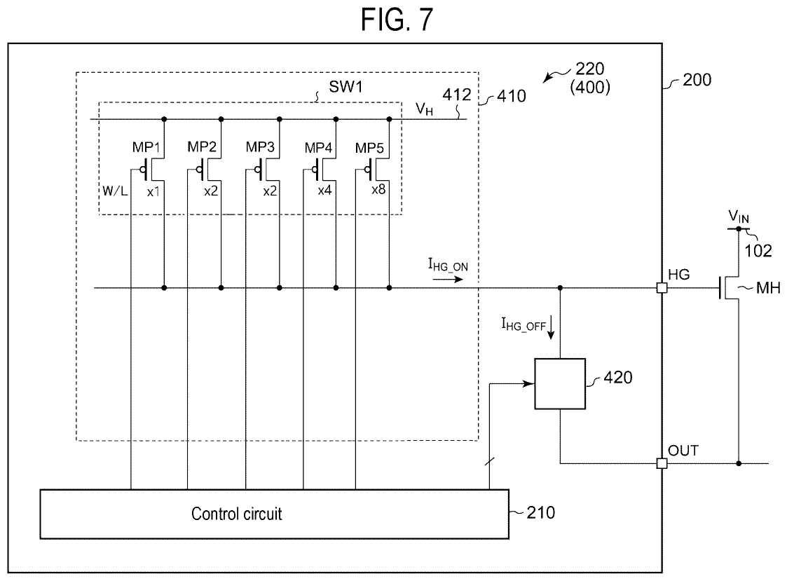

FIG. 7 is a circuit diagram of a turn-on circuit 410 according to modification 2.

The capabilities (sizes) of the plurality of transistors MP1 to MPn constituting the turn-on transistor SW1 are weighted in binary. In this example, n=5, and the W/L ratios of the transistors MP1, MP2, . . . . MP5 may satisfy the following relationship: 1:2:2:4:8.

Among the plurality of transistors MP1 to MP5, the transistors MP1 and MP2 are assigned to a first transistor group, and the transistors MP3 to MP5 are assigned to a second transistor group. States of the first transistor group are fixed over the first period T1 to the third period T3. For example, the transistor MP1 is fixed to an off state, and the transistor MP2 is fixed to an on state. The second current amount I₂ in the second period T2 can be set by combining states of the two transistors MP1 and MP2. In the second period T2, the transistors MP3 to MP5 included in the second transistor group are all fixed to an off state.

In the first period T1, the third period T3, and the fourth period T4, the transistors MP3 to MP5 included in the second transistor group are switched on and off.

An example of control in this case is shown below.

(i) First Period T1
MP1 =OFF
MP2 =ON
MP3 =OFF
MP4 =ON
MP5 =OFF
The capability of the turn-on transistor SW1 during the first period T1 is W/L =6.

(ii) Second Period T2
MP1 =OFF
MP2 =ON
MP3 =OFF
MP4 =OFF
MP5 =OFF
The capability of the turn-on transistor SW1 during the second period T2 is W/L =2.

(iii) Third Period T3
MP1 =OFF
MP2 =ON
MP3 =OFF
MP4 =OFF
MP5 =ON
The capability of the turn-on transistor SW1 during the third period T3 is W/L =10.

(iv) Fourth Period T4
MP1 =OFF
MP2 =ON
MP3 =ON
MP4 =ON
MP5 =ON
The capability of the turn-on transistor SW1 during the fourth period T4 is W/L =16.

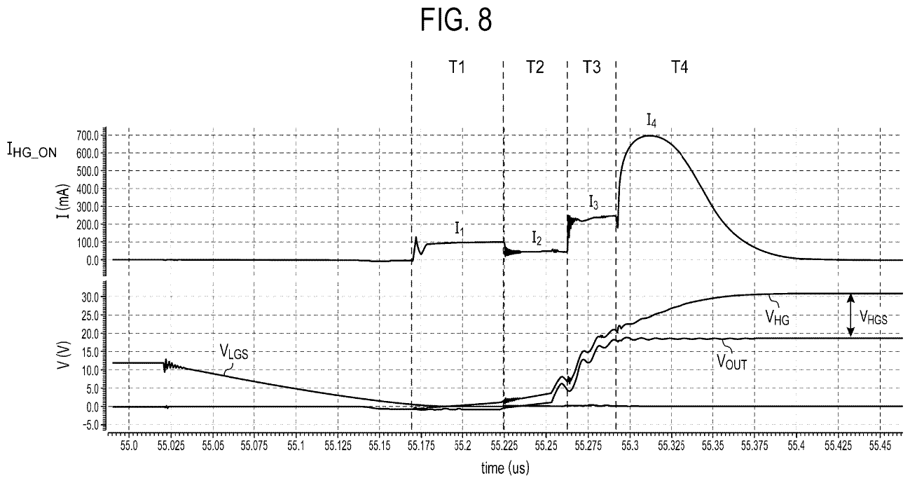

FIG. 8 is a waveform diagram showing an operation (simulation results) of the turn-on circuit 410 shown in FIG. 7.

In this configuration, the second current amount I₂ in the second period T2 can be set in three stages.

In addition, at the time of transition from the first period T1 to the second period T2, turning-on of any transistor does not occur but only turning-off occurs. In addition, at the time of transition from the second period T2 to the third period T3, turning-off of any transistor does not occur but only turning-on occurs.

If both turning-on and turning-off exist at the time of transition from the first period T1 to the second period T2 or from the second period T2 to the third period T3, discontinuity in a current may occur when timings of the turning-on and the turning-off are misaligned. Modification 2 can solve this problem.

In the fourth period T4, the transistor MP1 may be turned on.

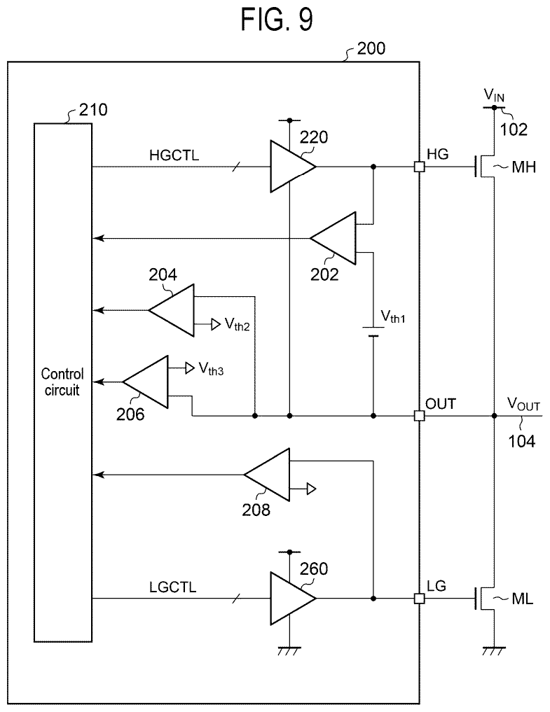

FIG. 9 is a circuit diagram of the drive circuit 200. The drive circuit 200 may include a first sensor 202, a second sensor 204, a third sensor 206, and a low-side off sensor 208.

The low-side off sensor 208 detects turning-off of the low-side transistor ML. The low-side off sensor 208 compares the gate-source voltage of the low-side transistor ML with the fourth threshold voltage Vₜₕ₄. When the control circuit 210 detects turning-off of the low-side transistor ML based on an output of the low-side off sensor 208, the control circuit 210 performs a transition to the first period T1.

The first sensor 202 compares the gate-source voltage V_{GS} of the high-side transistor MH with the first threshold voltage Vₜₕ₁. The first threshold voltage Vₜₕ₁ may be set based on a threshold voltage V_{GS(th)} of a MOSFET.

In many cases, a high-side off sensor that detects turning-off of the high-side transistor MH is provided in the drive circuit 200. An output of the high-side off sensor is referenced by the control circuit 210. The control circuit 210 monitors the output of the high-side off sensor, and performs a transition of the low-side control signal LGCTL to an on level after the high-side transistor MH is definitely turned off. Thus, it is possible to prevent the high-side transistor MH and the low-side transistor ML from being turned on simultaneously, and a through-current is prevented.

When the drive circuit 200 includes the high-side off sensor, the first sensor 202 may be shared with the high-side off sensor, thereby reducing the circuit area.

In the first period T1, the high-side driver circuit 220 performs a transition to the second period T2 when the output of the first sensor 202 is changed, i.e., when the gate-source voltage Vas of the high-side transistor MH exceeds the first threshold voltage Vₜₕ₁. When the first threshold voltage Vₜₕ₁ is set to be lower than the threshold voltage V_{GS(th)} of the MOSFET, the high-side driver circuit 220 can transition to the second period T2 before the high-side transistor MH is turned on. When a response delay is large, the high-side driver circuit 220 performs a transition to the second period T2 simultaneously with or slightly after the turning-on.

By monitoring the gate-source voltage V_{GS} of the high-side transistor MH, it is possible to change a magnitude of the drive current I_{HG_ON} in conjunction with the transition of the high-side transistor MH from an off state to an on state.

The second sensor 204 compares the output voltage V_{OUT} of the output line 104 with the second threshold voltage Vₜₕ₂. The high-side driver circuit 220 performs a transition to the third period T3 in response to a change in an output of the second sensor 204 in the second period T2. By monitoring the output voltage V_{OUT}, it is possible to detect that the influence of the reverse recovery characteristic of the flywheel diode Di of the lower arm 114 has become smaller.

The drive circuit 200 may be provided with a sensor (voltage monitoring circuit) that compares the output voltage V_{OUT} with a threshold voltage, which is lower than the input voltage V_{IN} by a predetermined value, for the purpose of detecting completion of the transition of the output voltage Vour from a low level to a high level, or for other purposes. In this case, by using the voltage monitoring circuit also as the second sensor 204, it is possible to suppress an increase in the circuit area.

The third sensor 206 compares the output voltage Vour with the third threshold voltage Vₜₕ₃ that is set in a vicinity of the input voltage V_{IN}. The control circuit 210 refers to an output of the third sensor 206, and performs a transition to the fourth period T4 when the output voltage V_{OUT} exceeds the third threshold voltage Vₜₕ₃.

Next, a configuration and operation of the low-side driver circuit 260 will be described. The low-side driver circuit 260 can be configured in the same manner as the high-side driver circuit 220.

The low-side driver circuit 260 operates in a first mode under a situation where a reverse recovery current of the flywheel diode of the upper arm 112 may be generated, and operates in a second mode under a situation where the reverse recovery current of the flywheel diode of the upper arm 112 is not generated.

Specifically, the low-side driver circuit 260 operates in the first mode under a situation (sink fall) where the low-side transistor ML is turned on from a state φ1B, in which the high-side transistor MH and the low-side transistor ML are turned off and the current lour is sinking via the flywheel diode Di of the upper arm 112.

In addition, the low-side driver circuit 260 operates in the second mode under a situation (source fall) where the low-side transistor ML is turned on from a state, in which the high-side transistor MH is turned on, the low-side transistor ML is turned off, and the current I_{OUT} is being sourced via the high-side transistor MH.

### Applications

Next, applications of the switching circuit 100 will be described. The switching circuit 100 can be appropriately used in a motor drive circuit.

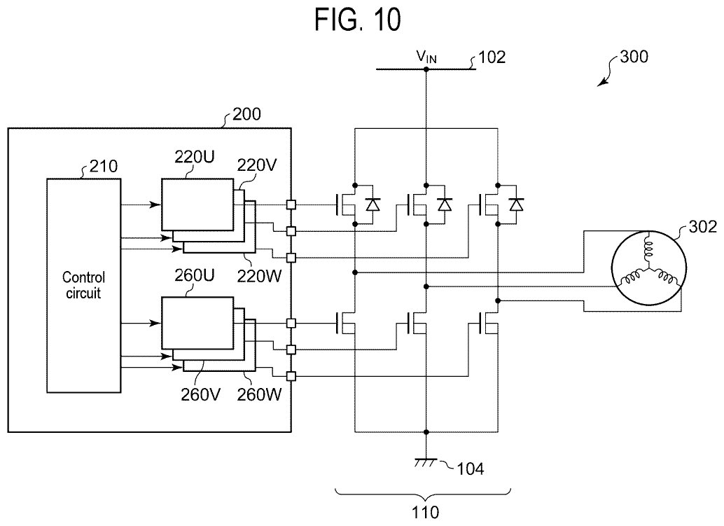

FIG. 10 is a circuit diagram of a motor drive device 300 including the switching circuit 100 according to the embodiment. The motor drive device 300 drives a three-phase motor 302, which is a load, and controls a rotation state thereof.

The motor drive device 300 includes a bridge circuit 110 and a drive circuit 200. The bridge circuit 110 is a three-phase inverter and has U-phase, V-phase, and W-phase legs. Each phase leg has an upper arm and a lower arm.

The drive circuit 200 includes a control circuit 210, high-side driver circuits 220U to 220W, and low-side driver circuits 260U to 260W. The control circuit 210 generates control signals indicating states of six arms that constitute the bridge circuit 110, based on a state of the three-phase motor 302, which is a load.

The high-side driver circuits 220U to 220W are configured with the architecture of the above-mentioned high-side driver circuit 220. The low-side driver circuits 260U to 260W are configured with the architecture of the above-mentioned low-side driver circuit 260.

Although the three-phase motor is used as an example here, a single-phase motor may also be used. In this cases the bridge circuit 110 is an H-bridge circuit.

Next, applications of the motor drive device 300 will be described. The motor drive device 300 can be used to control a spindle motor of a hard disk, or a lens drive motor of an imaging device. Alternatively, the motor drive device 300 can be used to head drive a drive motor or a paper feed motor for a printer. Alternatively, the motor drive device 300 can be used to drive a motor in an electric vehicle, a hybrid vehicle, or the like.

The embodiment is merely an example, and it will be understood by those skilled in the art that various modifications can be made in the combinations of respective components and respective processing steps, and that such modifications also fall within the scope of the present disclosure or the present invention. Such modifications will be described below.

### Modification 1

In the embodiment, the bridge circuit 110 is configured with discrete components. However, the present disclosure is not limited thereto. The bridge circuit 110 may be integrated into the drive circuit 200.

### Modification 2

The upper arm 112 and the lower arm 114 may be formed of IGBTs (Insulated Gate Bipolar Transistors).

### Modification 3

In the embodiment, both the high-side driver circuit 220 and the low-side driver circuit 260 are capable of selecting a plurality of modes. However, only one of them may be configured to be mode controllable.

### Modification 4

The application of the switching circuit 100 is not limited to the motor drive device 300. For example, the switching circuit 100 can be appropriately used in switching regulators (DC/DC converters), various power conversion devices (inverters and converters), inverters for turning discharge lamps on, digital audio amplifiers, and the like. Therefore, the switching circuit 100 can be used in consumer devices including electronic devices and home appliances, vehicles or in-vehicle components, and industrial vehicles or industrial machinery.

The embodiment described using specific terms merely illustrates the principles and applications of the present disclosure, and many modifications and changes in arrangement are permitted in the embodiment without departing from the spirit of the present disclosure as defined in the claims.

### Supplementary Notes

The following techniques are disclosed in this specification.

### Supplementary Note 1

A gate driver circuit for driving an N-type power transistor that constitutes a switching circuit, comprising:
a high-level line on which a voltage higher than a source of the power transistor is generated;
a turn-on transistor configured to source a current to a gate of the power transistor;
a turn-off transistor configured to sink a current from the gate of the power transistor; and
a control circuit configured to control the turn-on transistor and the turn-off transistor,
wherein the turn-on transistor includes a plurality of transistors connected between the gate of the power transistor and the high-level line, and
wherein the control circuit controls on/off states of the plurality of transistors so that when turning the power transistor on, the turn-on transistor has a first drive capability in a first period, a second drive capability lower than the first drive capability in a second period, and t a third drive capability higher than the second drive capability in a third period.

### Supplementary Note 2

The gate driver circuit of Supplementary Note 1, wherein the third drive capability is higher than the first drive capability.

### Supplementary Note 3

The gate driver circuit of Supplementary Note 1 or 2, wherein the plurality of transistors include at least one transistor assigned to a first transistor group and at least one transistor assigned to a second transistor group, and
wherein the control circuit fixes the at least one transistor assigned to the second transistor group to an off state during the second period, without changing the on-off state of the at least one transistor assigned to the first transistor group from the first period to the third period.

### Supplementary Note 4

The gate driver circuit of any one of Supplementary Notes 1 to 3, wherein the control circuit controls the on/off states of the plurality of transistors so that the turn-on transistor has a fourth drive capability higher than the third drive capability in a fourth period.

### Supplementary Note 5

The gate driver circuit of any one of Supplementary Notes 1 to 4, wherein the plurality of transistors have a same size.

### Supplementary Note 6

The gate driver circuit of any one of Supplementary Notes 1 to 4, wherein the plurality of transistors have binary weighted sizes.

### Supplementary Note 7

The gate driver circuit of any one of Supplementary Notes 1 to 6, further comprising a first sensor configured to compare a gate-source voltage of the power transistor with a first threshold voltage,
wherein the control circuit performs a transition to the second period in response to a change in an output of the first sensor during the first period.

### Supplementary Note 8

The gate driver circuit of any one of Supplementary Notes 1 to 7, further comprising a second sensor configured to compare an output voltage of the switching circuit with a second threshold voltage,
wherein the control circuit performs a transition to the third period in response to a change in an output of the second sensor during the second period.

### Supplementary Note 9

The gate driver circuit of Supplementary Note 4, further comprising a third sensor configured to compare an output voltage of the switching circuit with a third threshold voltage,
wherein the control circuit performs a transition to the fourth period in response to a change in an output of the third sensor during the third period.

### Supplementary Note 10

The gate driver circuit of any one of Supplementary Notes 1 to 9, which is integrated on a single semiconductor substrate.

### Supplementary Note 11

A motor drive device comprising:
a bridge circuit including a high-side transistor and a low-side transistor;
a high-side driver which is the gate driver circuit of any one of Supplementary Notes 1 to 9 configured to drive the high-side transistor as the power transistor; and
a low-side driver which is the gate driver circuit of any one of Supplementary Notes 1 to 9 configured to drive the low-side transistor as the power transistor.

### Supplementary Note 12

An electronic device comprising:
a motor; and
the motor drive device of Supplementary Note 11 configured to drive the motor.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A gate driver circuit for driving an N-type power transistor that constitutes a switching circuit, comprising:
a high-level line on which a voltage higher than a source of the power transistor is generated;
a turn-on transistor configured to source a current to a gate of the power transistor;
a turn-off transistor configured to sink a current from the gate of the power transistor; and
a control circuit configured to control the turn-on transistor and the turn-off transistor,
wherein the turn-on transistor includes a plurality of transistors connected between the gate of the power transistor and the high-level line, and
wherein the control circuit controls on/off states of the plurality of transistors so that when turning the power transistor on, the turn-on transistor has a first drive capability in a first period, a second drive capability lower than the first drive capability in a second period, and a third drive capability higher than the second drive capability in a third period.

2. The gate driver circuit of claim 1, wherein the third drive capability is higher than the first drive capability.

3. The gate driver circuit of claim 1, wherein the plurality of transistors include at least one transistor assigned to a first transistor group and at least one transistor assigned to a second transistor group, and
wherein the control circuit fixes the at least one transistor assigned to the second transistor group to an off state during the second period, without changing the on/off state of the at least one transistor assigned to the first transistor group from the first period to the third period.

4. The gate driver circuit of claim 1, wherein the control circuit controls the on/off states of the plurality of transistors so that the turn-on transistor has a fourth drive capability higher than the third drive capability in a fourth period.

5. The gate driver circuit of claim 1, wherein the plurality of transistors have a same size.

6. The gate driver circuit of claim 1, wherein the plurality of transistors have binary weighted sizes.

7. The gate driver circuit of claim 1, further comprising a first sensor configured to compare a gate-source voltage of the power transistor with a first threshold voltage,
wherein the control circuit performs a transition to the second period in response to a change in an output of the first sensor during the first period.

8. The gate driver circuit of claim 1, further comprising a second sensor configured to compare an output voltage of the switching circuit with a second threshold voltage,
wherein the control circuit performs a transition to the third period in response to a change in an output of the second sensor during the second period.

9. The gate driver circuit of claim 4, further comprising a third sensor configured to compare an output voltage of the switching circuit with a third threshold voltage,
wherein the control circuit performs a transition to the fourth period in response to a change in an output of the third sensor during the third period.

10. The gate driver circuit of claim 1, which is integrated on a single semiconductor substrate.

11. A motor drive device comprising:
a bridge circuit including a high-side transistor and a low-side transistor;
side driver which is the gate driver circuit of claim 1 configured to drive the high-side transistor as the power transistor; and
a low-side driver which is the gate driver circuit configured to drive the low-side transistor as the power transistor.

12. An electronic device comprising:
a motor; and
the motor drive device of claim 11 configured to drive the motor.
